(19) United States
(12) Patent Application Publication
(10) Pub. No.: US 2020/0243794 A1
(43) Pub. Date: Jul. 30, 2020

(54) DISPLAY DEVICE

(71) Applicant: FlexEnable Limited, Cambridgeshire (GB)

(72) Inventors: Simon Jones, Cambridgeshire (GB); William Reeves, Cambridgeshire (GB)

(21) Appl. No.: 16/648,834

(22) PCT Filed: Sep. 18, 2018
(86) PCT No.: PCT/GB2018/052653

§ 371 Date: Mar. 19, 2020

(30) Foreign Application Priority Data
Sep. 20, 2017 (GB) 1715159.8

(51) Int. Cl. H01L 51/52; G02F 1/1335; H01L 27/32; G02F 1/1333; G02F 1/1362

(52) U.S. Cl. CPC H01L 51/5237; G02F 1/133528; H01L 27/3234; H01L 2251/308; H01L 27/323; H01L 27/3276; G02F 1/136286; G02F 1/13338

(57) ABSTRACT

We disclose herein a display device comprising a first encapsulation layer, a second encapsulation layer disposed over the first encapsulation layer and spaced from the first encapsulation layer, a display medium disposed between the first and second encapsulation layers and at least one optical device located underneath the first encapsulation layer and the display medium. The at least the first encapsulation layer overlies the at least one optical device.

### TECHNICAL FIELD

The present disclosure relates to a display device, particularly but exclusively, to a display device having at least one transparent window within the display device.

### BACKGROUND

Display devices such as Liquid Crystal Displays (LCDs) or Light Emitting Diodes (LEDs) are known in the art. These displays are generally used in various electronic devices such as a mobile device. LCDs sometimes have physical holes through (e.g. watches or for a speaker on a smart phone), but making holes in glass is difficult. It is not also cost effective to make holes in the glass substrates. Furthermore, if a hole was made through the liquid crystal (LC) layer and the glass substrates (encapsulation layers), an encapsulation edge seal is generally necessary. This seal reduces LCD (or Organic LCD) active area on a display surface. Holes are generally placed at an edge of the display device and outside the active display area.

### SUMMARY

The disclosure generally relates to a method for enabling cameras and optical sensors to work through, for example, LCDs without having to cut a hole or cavity in the substrates (encapsulation layers) or seal the LC around a hole. This is achieved, for example, by cutting a hole in the polariser layers only and routing the conductive lines around a defined transparent window in the LCDs.

This increases the number applications that can be addressed with OLCDs and increases the potential maximum OLCD active-area on a product surface. Advantageously, the inactive area around the transparent window is less than with a hole as no LC sealing is required.

The proposed display device could be broadly applicable for video conferencing systems, as sensors and cameras are being more tightly integrated with displays. LCDs sometimes have physical holes through (e.g. watches), but making holes in glass is difficult. There is no use of transparent windows in the middle of LCD displays for sensors and cameras. As displays become three dimensional (3D) and more product specific, there will be increased opportunity and demand for product specific features including transparent windows.

The technical advantage is that cameras and sensors can operate through the LCD display without the need to cut a hole through the display material and to seal LC around the hole or cavity. The optical appearance of the display will be more homogeneous than that provided by a physical hole.

According to one aspect of the present disclosure, there is provided a display device comprising:
a first encapsulation layer;
a second encapsulation layer disposed over and spaced from the first encapsulation layer;
a display medium disposed between the first and second encapsulation layers;
at least one optical device located underneath the first encapsulation layer and the display medium; and
wherein at least the first encapsulation layer overlies the at least one optical device.

The display medium and the second encapsulation layer may each overlie the at least one optical device. The at least one of the first and second encapsulation layers may not have a cavity in a corresponding location of the optical device underneath.

Preferably, the display medium does not have a cavity in a corresponding location of the optical device. Preferably, the first and second encapsulation layers are substantially optically transparent. This enables the optical device (e.g. a camera or an optical sensor) to operate through the substantially transparent encapsulation (or glass substrate) layers. Advantageously, there is no need to create a hole or cavity in the substrate and therefore the process is cheaper.

The display device may further comprise at least one transparent window region disposed underneath the first encapsulation layer, and wherein the at least one optical device is located in the at least one transparent window region. In other words, the transparent window region is a target region where the optical device is provided. The target region is transparent because it is a region formed by cutting a portion of a polariser or a general target region underneath the first encapsulation layer.

The display device may further comprise a first polariser underneath the first encapsulation layer. The at least one transparent window region may be a cavity or an opening within the first polariser. The cavity is not generally filled in with a material, but the cavity is provided with the optical device.

The display device may further comprise a backlight region underneath the first polariser. The at least one transparent window region of the first polariser may extend within the backlight region. The at least one optical device may be located at least partially within the first polariser and at least partially within the backlight region.

The display device may further comprise a second polariser over the second encapsulation layer. The display device may comprise a further transparent window region within the second polariser. The further transparent window is generally a further cavity or a further opening in the second polariser. The position of the further transparent window region in the second polariser may be substantially aligned with the position of the transparent window in the first polariser. In other words, the cavity in the first polariser is substantially vertically aligned to the cavity in the second polariser. The further transparent window region in the second polariser may comprise a transparent material.

The display device may further comprise a touch sensing layer on the second polariser; and a cover window on the touch sensing layer.

The display device may further comprise a plurality of conductive lines, at least some of the conductive lines being routed around the at least one transparent window region.

The display device may further comprise a plurality of conductive lines, at least some of the conductive lines being routed through the at least one transparent window region.

The at least some of the conductive lines routed through the transparent window region may comprise a transparent material. The transparent material may comprise indium tin oxide (ITO).

The transparent material may have an index of refraction that is similar or closely approximate to that of the first encapsulation layer. The transparent material may be index matched with the first encapsulation layer so that the conductive lines within the transparent window region do not obstruct the operation of the at least one optical device.

The display device may further comprise a continuous layer of a non-conducting material between the at least some of the conductive lines and the first encapsulation layer, the continuous layer having a similar refractive index compared to the conductive lines.

The display device may comprise an active display area which extends to a perimeter region of the at least one transparent window region. Advantageously this increases active display area within the display device.

The display device may be configured such that light is selectively passed through the at least one transparent window region. For instance if the transparent window region actually incorporated a large switchable area (or pixel) then the amount of light passed through the transparent window area could be modulated. This could potentially be useful if the application required the implementation of “neutral density filters”—for instance to build up a high dynamic range (HDR) image.

The display device may further comprise a plurality of transparent window regions each having said optical device, wherein each transparent window is laterally spaced from one another.

The plurality of transparent window regions may be spread or distributed from one side of the display device to another opposite side of the display device. The plurality of transparent window regions may be spread through a middle portion of the display device.

The plurality of transparent window regions may each correspond to an inactive display area. In these areas, the display pixels are inactive but the optical device (camera or optical device) can be active.

The display medium may be a liquid crystal display (LCD) medium.

The display medium may be an organic light emitting diode (OLED) display medium.

At least one of the first and second encapsulation layers may be a glass substrate.

The display device may be any one of a flat display device, and a three-dimensional curved display device having a curved display portion. The at least one transparent window region and the optical device may be located in the curved display portion.

The optical device may be any one of: a camera; an optical sensor, and/or a motion sensor.

According to a further aspect of the present disclosure, there is provided a method of manufacturing a display device, the method comprising:
forming a first encapsulation layer;
forming a display medium over the first encapsulation layer;
forming a second encapsulation layer over the display medium;
providing at least one optical device underneath the first encapsulation layer and the display medium,
wherein at least the first encapsulation layer overlies the at least one optical device.

The method may comprise forming at least one transparent window region underneath the first encapsulation layer, and providing the at least one optical device within the at least one transparent window region. The method may comprise forming a first polariser underneath the first encapsulation layer and forming a backlight layer underneath the first polariser.

The at least one transparent window region may be formed by cutting a cavity within the first polariser and the backlight region.

The method may comprise forming a second polariser over the second encapsulation layer and forming a further transparent window region within the second polariser.

The method may comprise filling the further transparent window region with a transparent material.

The method may comprise forming a plurality of conductive lines, at least some of the conductive lines being routed around the transparent window region.

The method may comprise forming a plurality of conductive lines, at least some of the conductive lines being routed through the transparent window region.

The at least some of the conductive lines routed through the transparent window region comprise a transparent material.

The method may comprise forming a continuous layer of a non-conducting material between the at least some of the conductive lines and the first encapsulation layer, the continuous layer having a similar refractive index compared to the conductive lines.

### BRIEF DESCRIPTION OF THE DRAWINGS

Some preferred embodiments of the disclosure will now be described by way of an example only and with reference to the accompanying drawings, in which:

FIG. 1 illustrates a schematic cross-sectional view of a conventional structure of a liquid crystal display;

FIG. 2 illustrates a top view of the LCD structure of FIG. 1;

FIG. 3 illustrates a schematic cross-sectional view of a LCD structure having a hole through the display layers;

FIG. 4 illustrates a top view of the LCD structure of FIG. 3;

FIG. 5 illustrates a schematic cross-sectional view of an alternative LCD structure having a hole through the display layers;

FIG. 6 illustrates a schematic cross-sectional view of an alternative LCD structure having a transparent window by cutting a hole in both polarisers according to one embodiment of the present disclosure;

FIG. 7 illustrates a schematic cross-sectional view of an alternative LCD structure having a transparent window by cutting a hole in the lower polariser according to one embodiment of the present disclosure;

FIG. 8 illustrates a top view of an alternative LCD structure according to one embodiment of the present disclosure;

FIG. 9 illustrates a top view of an alternative LCD structure according to one embodiment of the present disclosure;

FIG. 10 illustrates a schematic cross-sectional view of an alternative LCD structure having a touch sensor and a cover window according to one embodiment of the present disclosure; and

FIG. 11 illustrates a schematic cross-sectional view of an OLED display device according to one embodiment of the present disclosure.

### DETAILED DESCRIPTION OF THE PREFERRED EMBODIMENTS

FIG. 1 illustrates a schematic cross-sectional view of a conventional structure of a liquid crystal display 100. In this known structure 100, liquid crystal (LC) material 130 is disposed between a bottom (or first) encapsulation layer 115 and a top (or second) encapsulation layer 140. The LC material 130 is sandwiched by a LC cell top layer 135 and a LC cell bottom layer 120. An edge seal 125 is provided on both sides of the LC material 130. The LC layers are generally driven by control circuitry (not shown), for example, thin film transistors (TFTs) and associated electrical connections, disposed on the LC cell bottom 120. The control circuitry generally includes an array of thin film transistors (TFTs). The encapsulation layer 115, in the case of OLCD, can be a thin film.

In the structure of FIG. 1, a first polariser film or layer 110 is provided below the bottom encapsulation layer 115. A backlight layer 105 is provided below the first polariser film 110. The bottom encapsulation layer 115 could generally be a glass substrate. In the example of FIG. 1 which is an OLCD, the LC cell bottom 120 and LC cell top 140 are generally made of TAC (Cellulose Triacetate). The bottom encapsulation layer 115 may include an indium tin oxide (ITO) layer (not shown). The bottom encapsulation layer 115 and the first polariser film 110 generally form part of a driver component 76 of the display structure 100. The backlight layer 105 is generally a separate part.

In the structure of FIG. 1, a second polariser film 145 is provided on the top encapsulation layer 140. In one example, one side of the top encapsulation layer 140 there is provided a colour filter layer (not shown). It will be appreciated that in conventional LCD the colour filter resides on the “LC cell top” layer 135. The encapsulation layer 140 may not be required if the “LC cell Top” is made of glass. In the case of OLCD the encapsulation film 140 is generally provided. The encapsulation film 140 could be integrated into the polariser 145 or “LC cell top” layer 135. The second polariser film 145, the top encapsulation layer 140 generally form part of a colour filter component 78 of the structure 100. The top encapsulation layer 140 is generally a glass substrate, for example, in OLCDs. The top encapsulation layer 140 could be a flexible organic-inorganic barrier.

In the structure of FIG. 1, two dashed lines show a target area where a hole or cavity or a transparent window region can be made within the LCD structure 100.

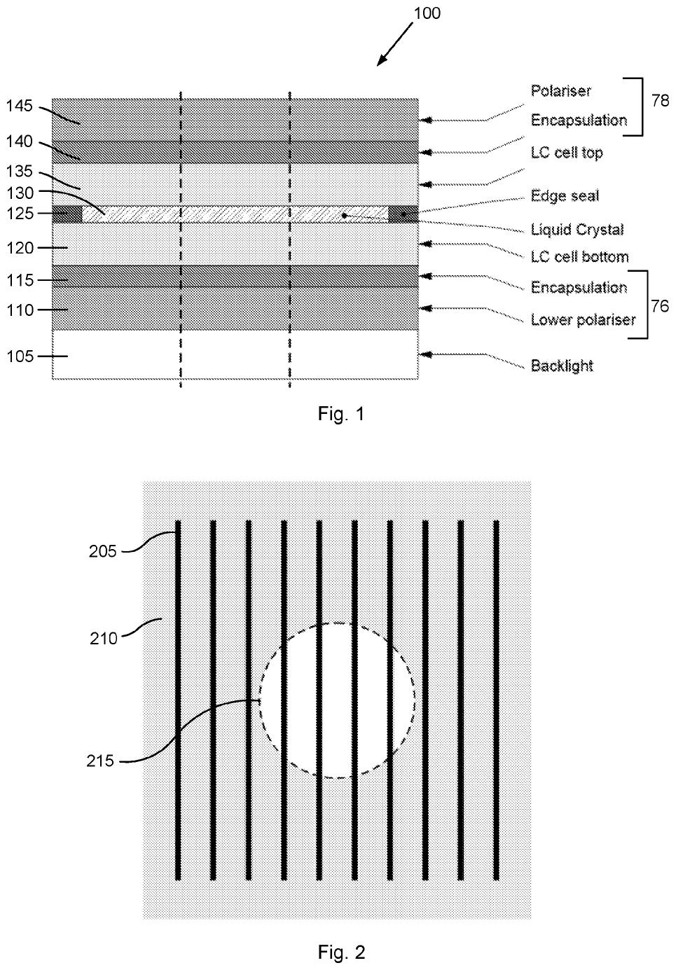

FIG. 2 illustrates a top view of the LCD structure of FIG. 1. In this figure, conductive routing lines 205 are shown which are extending in one direction. It will be appreciated that conductive routing lines are also provided in a perpendicular direction (not shown here for ease of representation) of the routing lines 205. The glass substrate 210 (or the encapsulation layer) is shown by the overall rectangle area. In one example, the grey shaded rectangle area 21 represents the active, or driveable, pixels. The dotted circle 215 corresponds to the target hole or cavity area.

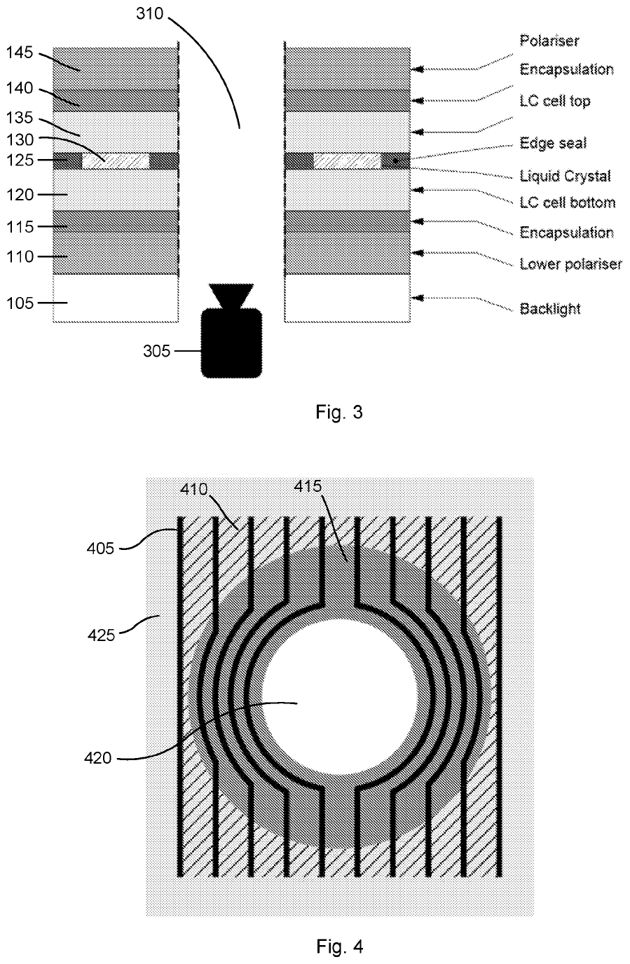

FIG. 3 illustrates a schematic cross-sectional view of a LCD structure having a hole through all the layers of the display device. Many features of FIG. 3 are the same as those shown in FIG. 1 and therefore carry the same reference numbers. However, in the structure of FIG. 3, a hole (or a transparent window) 310 is made through all the layers of the LCD structure. For example, the hole 310 is made through the backlight layer 105, the first polariser 110, the bottom encapsulation layer 115, the LC cell bottom 120, the LC material 130, edge seal 125, LC cell top layer 135, the top encapsulation layer 140 and the second polariser 145. An optical device 305 is also provided within the hole (but partially near the lower polariser 110 and the backlight layer 105, or really close to the top). The optical device 305 could be a camera or an optical sensor such as an image sensor or motion sensor. Because the hole 310 is created through the LC material 130, the edge seal 125 is also provided adjacent the hole 310. This edge seal 125 reduces the active display area within the display device. It is also difficult to create holes through the substrate glasses of the LCD device.

FIG. 4 illustrates a top view of the LCD structure of FIG. 3. The hole (or the transparent window) 420 is created through all the layers of the LCD display. As a result, the encapsulation/edge seal 415 is formed around the hole 420. A possible active area 410 is shown using shaded lines. The glass substrate 425 (or the encapsulation layer) is shown by the overall rectangle area. The conductive routing lines 405 are routed around the hole 420 within the encapsulation/edge seal 415. Because the encapsulation/edge seal 415 is extended around the hole 420, it reduces the active display area within the LCD display.

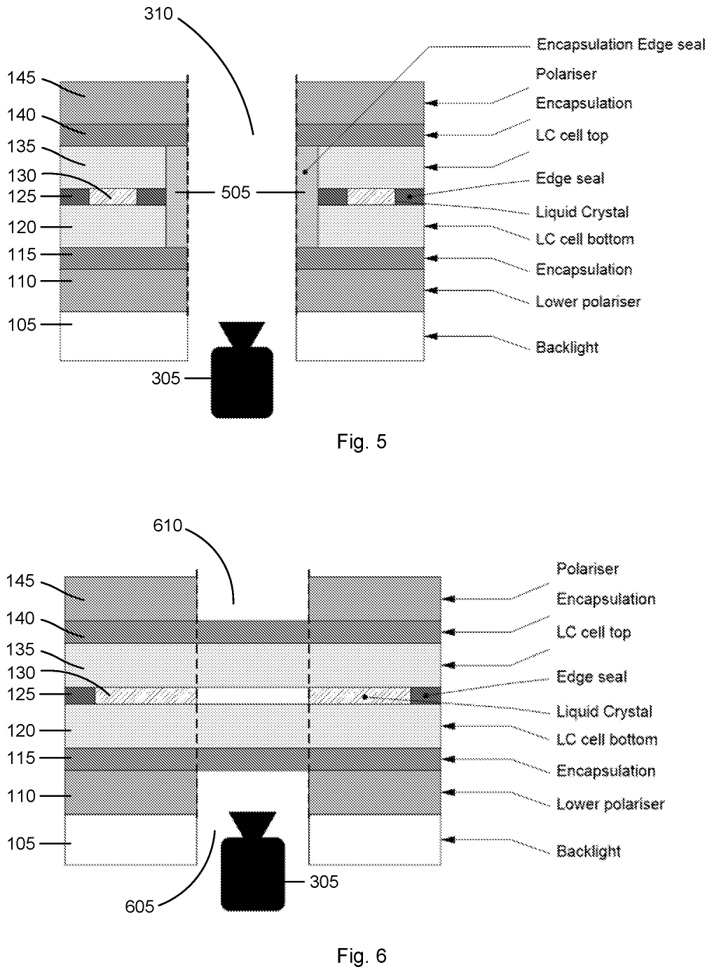

FIG. 5 illustrates a schematic cross-sectional view of an alternative LCD structure having a hole through the display layers. Many features of FIG. 5 are the same as those shown in FIG. 3 and therefore carry the same reference numbers. However, in the structure of FIG. 5, there is an encapsulation edge seal 505 adjacent the hole 310. This additional seal 505 is generally provided in addition to the LC edge seal 125 and would therefore further decrease the amount of “active area” available within the LCD device.

FIG. 6 illustrates a schematic cross-sectional view of an alternative LCD structure having a transparent window by cutting a hole in both polarisers according to one embodiment of the present disclosure. Many features of FIG. 6 are the same as those shown in FIG. 5 and therefore carry the same reference numbers. However, in the structure of FIG. 6, the hole is not created through all the layers of the LCD device. Instead, a first transparent window (or a first transparent opening or a first hole) 605 is created by forming a hole within the first polariser 110. The first transparent window 605 extends within the backlight region 105 as well. The camera or optical sensor 305 is provided within the first transparent window 605. A second transparent window (or a second transparent opening or a second hole) 610 is formed by cutting the second polariser 610 over the top encapsulation layer 140. In one embodiment, the gap (or the second transparent window) 610 in the top second polariser 145 is generally filled in with a transparent material when a touch sensor or cover window (not shown here) is formed over the second polariser 145. In one example, the diameter of the transparent window 605 is generally from about 5 mm to about 20 mm, preferably about 10 mm. In general, the diameter of the transparent window should be as small as possible to allow the smallest disruption to the viewing experience—it may also mean that the smallest number of routing lines are re-routed around the aperture.

Although one optical device 305 is provided within the first transparent window region 605 in the structure of FIG. 6, it will be appreciated that a plurality or an array of transparent windows each having an optical device (e.g. a camera or optical sensor) can be formed within the polariser film 110 underneath the active display area (produced by the LC material 130). The transparent windows 605 can be distributed throughout the display area, e.g. from one side of the display to another side, particularly to a middle portion of the display. All the transparent widows may have the same optical device (e.g. the cameras or optical sensors), or a mixture of different optical devices (e.g. some windows having cameras and other windows having optical sensors).

Advantageously, in the structure of FIG. 6, it is not required to create the hole through the glass substrates 115, 140 and therefore this structure does not use encapsulation edge seal (unlike the structure of FIG. 5). As a result, the active area within the display device is improved or increased in this structure. Furthermore, the structure of FIG. 6 provides an improved optical performance because the holes 605, 610 are made in both polariser films 110, 145. In the LCD structure of FIG. 6, both cameras and/or optical sensors 305 can be used within the first transparent window 605.

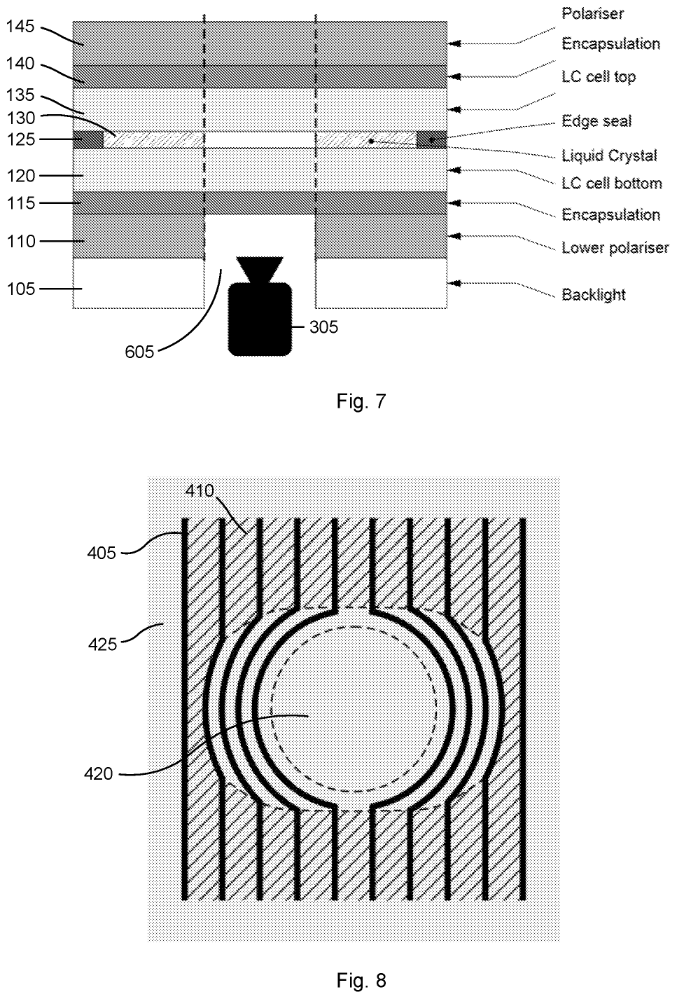

FIG. 7 illustrates a schematic cross-sectional view of an alternative LCD structure having a transparent window by cutting a hole in the lower polariser only according to one embodiment of the present disclosure. Many features of FIG. 7 are the same as those shown in FIG. 6 and therefore carry the same reference numbers. However, in the structure of FIG. 7, the second polariser film 145 is not cut—only the first lower polariser film 110 is cut to create the first transparent window 605. This structure is particularly suitable for light/3D sensors to be fitted within the first transparent window 605. Advantageously, in this configuration the front of the display would look more uniform. However, it may be possible to compromise 50% of the available light due to the polariser. Generally large area sensors are not as “light constrained” as imaging sensors and therefore this configuration is generally advantageous.

FIG. 8 illustrates a top view of an alternative LCD structure according to one embodiment of the present disclosure. Many features of the structure of FIG. 8 are the same as those in FIG. 4 and therefore carry the same reference numbers, except that the encapsulation seal 415 is removed in FIG. 8. This is because, in the structure of FIG. 8, the polariser film is cut to create the transparent window, but the glass substrates 425 or the LC material is not cut. It may be possible to make the transparent window area 420 “direct drive” to allow the area to selectively pass light. Routing aside, more active area is possible in this configuration since no edge seal is required.

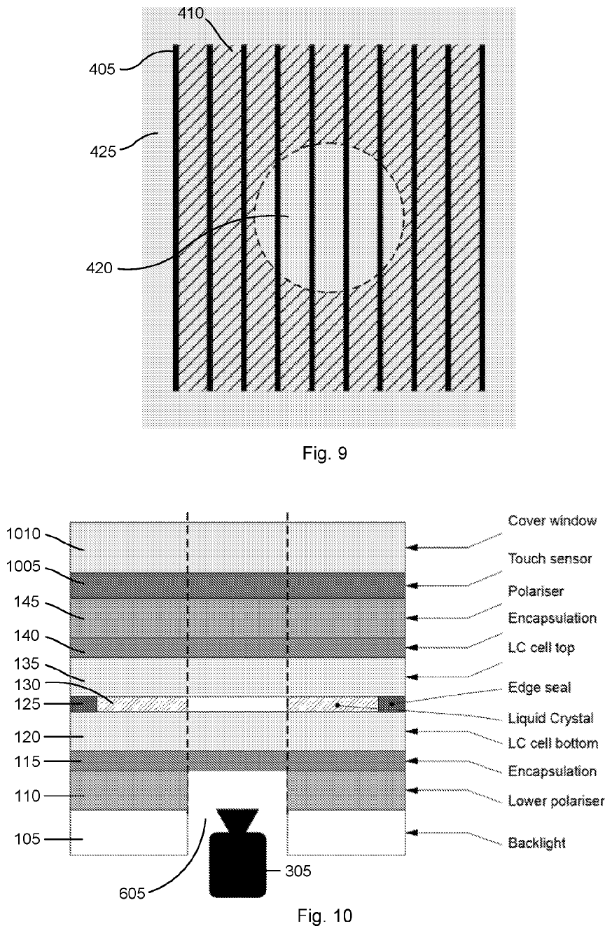

FIG. 9 illustrates a top view of an alternative LCD structure according to one embodiment of the present disclosure. Many features of the structure of FIG. 9 are the same as those in FIG. 8 and therefore carry the same reference numbers. However, in FIG. 9, the conductive routing lines 405 extend through the transparent window area 420. Preferentially the routing lines 405 are made of a transparent material (ITO for example). Furthermore, generally, the conductive routing lines 405 are indexed matched to the glass substrate (or the first encapsulation layer). The ITO lines 405 are generally indexed matched to a layer directly beneath (or above) them. That way when a light ray passes through the stack it sees the same refractive index changes and the lines are therefore hidden. The index matching is generally achieved via a localised deposition of a continuous layer (not shown) of a non-conducting material with a similar refractive index. This index matching generally reduces the amount of diffraction to a minimum or generally keeps the amount of reflection constant. For example, a large refractive index change results in a larger reflection at the interface. If index matching is not conducted, the reflection off the lines is usually seen and not the “gaps” which makes the pattern visible. If the index matching layer is applied the same reflection everywhere is generally achieved. Thus the only outcome seen is the additional absorption of the ITO—but this is generally reduced or minimal. Advantageously, this allows the active display area 410 to go almost right up to the edges (or the perimeter) of the transparent aperture 420 (or transparent window or the hole).

FIG. 10 illustrates a schematic cross-sectional view of an alternative LCD structure having a touch sensor and a cover window according to one embodiment of the present disclosure. Many features of FIG. 10 are the same as those shown in FIG. 7 and therefore carry the same reference numbers. However, in the structure of FIG. 10, a touch sensor 1005 is provided on the second polariser film 145 and a cover window 1010 is provided on the touch sensor 1005. Advantageously the display device is capable of having touch sensing operations over the camera/sensor aperture (or the transparent window).

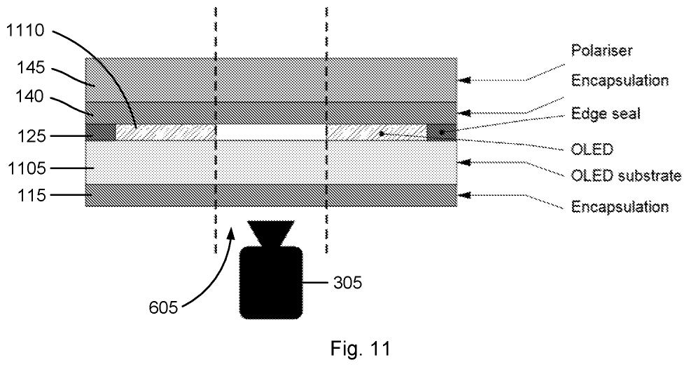

FIG. 11 illustrates a schematic cross-sectional view of an OLED display device according to one embodiment of the present disclosure. Many features of FIG. 11 are the same as those shown in FIG. 7 and therefore carry the same reference numbers. However, in the structure of FIG. 11, the LC material 130, the LC cell top 135 and the LC cell bottom 120 are replaced with an OLED device 1110 and an OLED transparent substrate 1105 underneath the OLED device 1110. In the OLED display device of FIG. 11, there is generally no first polariser underneath the encapsulation layer 115.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

1-41. (canceled)

42. A display device comprising:
a first encapsulation layer;
a second encapsulation layer disposed over and spaced from the first encapsulation layer;
a display medium disposed between the first and second encapsulation layers;
at least one optical device located underneath the first encapsulation layer and the display medium;
wherein at least the first encapsulation layer overlies the at least one optical device.

43. A display device according to claim 42, wherein the display medium and the second encapsulation layer each overlies the at least one optical device.

44. A display device according to claim 42, further comprising at least one transparent window region disposed underneath the first encapsulation layer, and wherein the at least one optical device is located in the at least one transparent window region.

45. A display device according to claim 44, further comprising a first polariser underneath the first encapsulation layer; and optionally wherein the at least one transparent window region is a cavity within the first polariser.

46. A display device according to claim 45, further comprising a backlight region underneath the first polariser; and
optionally wherein the at least one transparent window region of the first polariser extends within the backlight region; and
optionally wherein the at least one optical device is located at least partially within the first polariser and at least partially within the backlight region.

47. A display device according to claim 42, comprising a second polariser over the second encapsulation layer.

48. A display device according to claim 47, comprising a further transparent window region within the second polariser; and
optionally wherein the position of the further transparent window region in the second polariser is substantially aligned with the position of the transparent window in the first polariser.

49. A display device according to claim 48, wherein the further transparent window region in the second polariser comprises a transparent material; and/or
further comprising:
a touch sensing layer on the second polariser; and
a cover window on the touch sensing layer.

50. A display device according to any claim 44, further comprising a plurality of conductive lines, at least some of the conductive lines being routed around the at least one transparent window region.

51. A display device according to claim 44, further comprising a plurality of conductive lines, at least some of the conductive lines being routed through the at least one transparent window region; and
optionally wherein said at least some of the conductive lines routed through the transparent window region comprise a transparent material; and
optionally wherein the transparent material comprises indium tin oxide (ITO); and/or
wherein the transparent material has an index of refraction that is similar to that of the first encapsulation layer; and/or
wherein the transparent material is index matched with the first encapsulation layer so that the conductive lines within the transparent window region do not obstruct the operation of the at least one optical device.

52. A display device according to claim 51, further comprising a continuous layer of a non-conducting material between the at least some of the conductive lines and the first encapsulation layer, the continuous layer having a similar refractive index compared to the conductive lines; and/or
wherein the display device comprises an active display area which extends to a perimeter region of the at least one transparent window region.

53. A display device according to claim 44, wherein the display device is configured such that light is selectively passed through the at least one transparent window region; and/or
further comprising a plurality of transparent window regions each having said optical device, wherein each transparent window is laterally spaced from one another; and
optionally wherein said plurality of transparent window regions are spread from one side of the display device to another opposite side of the display device; and/or
wherein said plurality of transparent window regions are spread through a middle portion of the display device; and
optionally wherein said plurality of transparent window regions each corresponds to an inactive display area.

54. A display device according to claim 42, wherein the display medium is a liquid crystal display (LCD) medium; or
wherein the display medium is an organic light emitting diode (OLED) display medium.

55. A display device according to claim 44, wherein the display device is any one of:
a flat display device; and
a three-dimensional curved display device having a curved display portion; and
optionally wherein the at least one transparent window region and the optical device are located in the curved display portion.

56. A display device according to claim 42, wherein the optical device is any one of:
a camera;
an optical sensor, and/or
a motion sensor.

57. A method of manufacturing a display device, the method comprising:
forming a first encapsulation layer;
forming a display medium over the first encapsulation layer;
forming a second encapsulation layer over the display medium;
providing at least one optical device underneath the first encapsulation layer and the display medium,
wherein at least the first encapsulation layer overlies the at least one optical device.

58. A method according to claim 57, comprising forming at least one transparent window region underneath the first encapsulation layer, and providing the at least one optical device within the at least one transparent window region; and
optionally comprising forming a first polariser underneath the first encapsulation layer and forming a backlight layer underneath the first polariser; and
optionally wherein said at least one transparent window region is formed by cutting a cavity within the first polariser and the backlight region.

59. A method according to claim 57, comprising forming a second polariser over the second encapsulation layer and forming a further transparent window region within the second polariser.

60. A method according to claim 59, comprising filling the further transparent window region with a transparent material.

61. A method according to claim 57, comprising forming a plurality of conductive lines, at least some of the conductive lines being routed around the transparent window region; or
comprising forming a plurality of conductive lines, at least some of the conductive lines being routed through the transparent window region; and
optionally wherein said at least some of the conductive lines routed through the transparent window region comprise a transparent material; and
optionally comprising forming a continuous layer of a non-conducting material between the at least some of the conductive lines and the first encapsulation layer, the continuous layer having a similar refractive index compared to the conductive lines.
